(19) United States
(12) Patent Application Publication
(10) Pub. No.: US 2008/0026579 A1
(43) Pub. Date: Jan. 31, 2008

(54) COPPER DAMASCENE PROCESS

(76) Inventors: Kuo-Chih Lai, Tai-Nan City (TW); Mei-Ling Chen, Kao-Hsiung City (TW); Jei-Ming Chen, Taipei Hsien (TW); Hsin-Hsing Chen, Ping-Tung County (TW); Shih-Feng Su, Kao-Hsiung City (TW); Meng-Chi Chen, Tai-Nan City (TW)

Correspondence Address: NORTH AMERICA INTELLECTUAL PROPERTY CORPORATION, P.O. BOX 506, MERRIFIELD, VA, 22116, US

(21) Appl. No.: 11/459,931

(22) Filed: Jul. 25, 2006

(51) Int. Cl. H01L 21/44

(52) U.S. Cl. 438/687

(57) ABSTRACT

A copper damascene process includes providing a substrate having a dielectric layer thereon, forming at least a copper damascene structure in the dielectric layer, performing a heat treatment on the substrate, and performing a reduction plasma treatment on a surface of the copper damascene structure. The impurities formed in the copper damascene process are removed by the heat treatment, therefore the copper damascene structure is completely reduced by the reduction plasma treatment and is improved.

### BACKGROUND OF THE INVENTION

1. Field of the Invention

This invention relates to a copper damascene process, and more particularly, to a copper damascene process providing copper damascene structures having improved reliability.

2. Description of the Prior Art

With the progress of the semiconductor industry, performance and economic factors of integrated circuit design and manufacture have caused the scale of devices of integrated circuits to be drastically reduced in size and increased in proximity on a chip. However, performance of integrated circuits not only depends on reliability of the devices, but also relies on metal interconnections used to transmit signals between the devices. Therefore, integrated circuit fabrication on semiconductor structures for ultra scale integration (ULSI) requires multiple levels of metal interconnections for electrically connecting the miniaturized semiconductor devices. To overcome difficulties in fabricating metal interconnection in multi-layer, the damascene structure has been extensively researched and developed. In addition, because the resistive coefficient of copper is lower than that of other metals, such as aluminum, and copper has the advantage of better electro-migration resistance while low-k material effectively reduces resistance-capacitance (RC) delay effects between metal interconnections, single copper damascene structure and copper damascene structure have been widely used in fabrication of integrated circuits. Accordingly, the copper damascene process is taken as the technique that can solve metal interconnection problem of deep sub-half micro integrated circuits in the future.

Please refer to FIGS. 1-4, which are schematic drawings illustrating a conventional via-first copper damascene process. As shown in FIG. 1, a substrate 100 having a plurality of function devices thereon (not shown) is first provided. Then, a cap layer 110, a stacked dielectric layer 120, and a stop layer 128 composed of silicon nitride are sequentially formed on the substrate 100. The stacked dielectric layer 120 comprises a first dielectric layer 122, an etching stop layer 124, and a second dielectric layer 126. The cap layer 110, the stacked dielectric layer 120, and the stop layer 128 are etched by photolithography etching processes (PEPs) to form via holes 132, 142 and trenches 134, 144. Then, a diffusion barrier layer 150 is deposited on bottoms and sidewalls of the via holes 132, 142 and the trenches 134, 144. After forming the diffusion barrier layer 150, a copper metal layer filling the via holes 132, 142 and the trenches 134, 144 is formed on the substrate 100 by a seed layer and an electroplating process.

Please refer to FIG. 2. A chemical mechanical polishing, CMP) process is performed to remove surplus metal and form dual damascene structures 130 and 140. Then, the diffusion barrier layer 150 and the stop layer 128 are removed by another CMP or other etching method. Therefore surfaces of the dual damascene structures 130 and 140 are made coplanar with surface of the stacked dielectric layer 120. In addition, as shown in FIG. 2, a silicon nitride (SiN) or a silicon carbide (SiC) layer 160 is formed on the surfaces of the dual damascene structures 130, 140 and the stacked dielectric layer 120. The SiN or SiC layer 160 is not only used as the cap layer of the dual damascene structures 130, 140 and the stacked dielectric layer 120, but also is used to protect the copper atom of the dual damascene structures 130, 140 from diffusing along the interface between the dual damascene structures 130, 140 and the stacked dielectric layer 120.

Please refer to FIG. 3. Because copper is easily oxidized and corrupted during a CMP process, patterns of copper damascene structure on the wafer are protected by adding organic solutions, such as triazole, in the slurry used in copper CMP process. For reducing copper oxide 170 formed in the CMP process and removing the organic materials remaining after the CMP process, those skilled in the art used to perform a reduction treatment on the surface of the substrate 100 with a hydrogen-containing plasma and perform a heat treatment for evaporating and removing the impurities. However, residuals 172 are not removed completely in the prior art.

Please refer to FIG. 4. The residual 172 remaining on the surface of the copper damascene structure will obstruct the hydrogen-containing plasma from reducing the copper oxide 170 and even make the copper damascene structure malfunction. And the residual 172 remaining on the surface of the stacked dielectric layer 120 will cause blisters and reduce the adhesion between the stacked layer 120 and the SiN or SiC layer 160, thus the copper atom will diffuse out along the interface between the copper damascene structure 130, the stacked layer 120 and the SiN or SiC layer 160 and cause leakage current which reduces breakdown voltage of the dielectric layer then seriously affects reliability of the integrated circuit.

### SUMMARY OF THE INVENTION

Therefore the present invention provides a copper damascene process providing copper damascene structures having improved reliability.

According to the claimed invention, a copper damascene process is provided. The copper damascene process comprises steps of providing a substrate having a dielectric layer formed thereon, forming at least a copper damascene structure in the dielectric layer, performing a heat treatment on the substrate, and performing a reduction plasma treatment on a surface of the copper damascene structure.

According to the claimed invention, another copper damascene process is also provided. The copper damascene process comprises steps of providing a substrate having a dielectric layer formed thereon, forming at least a copper damascene structure in the dielectric layer, performing an oxidation plasma treatment on a surface of the substrate, and performing a reduction plasma treatment on a surface of the copper damascene structure.

According to the claimed invention, another copper damascene process is provided. The copper damascene process comprises steps of providing a substrate having a dielectric layer formed thereon, forming at least a copper damascene structure in the dielectric layer, performing an ultra violet (UV) treatment on a surface of the substrate, and performing a reduction plasma treatment on a surface of the copper damascene structure.

The object of present invention is achieved by alternatively performing a heat treatment, an oxidation plasma treatment, or a UV treatment which remove residuals formed in the copper damascene process after forming copper damascene structure. Therefore the reduction plasma treatment performed later can reduce copper oxide completely and improve the reliability of the copper damascene structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-4 are schematic drawings illustrating a conventional via-first copper damascene process.

FIGS. 5-8 are schematic drawings illustrating a first preferred embodiment provided by the invention.

FIG. 9 is a drawing illustrating normalized results of a voltage ramp dielectric breakdown (VRDB) test for conventional damascene structure and that provided by the present invention.

FIG. 10 is a drawing illustrating normalized results of a VRDB test for copper damascene structures provided by the present invention with different procedure parameters.

FIG. 11 is a schematic drawing illustrating a second and a third preferred embodiment.

FIG. 12 is a flowchart according to the copper damascene process provided by the invention.

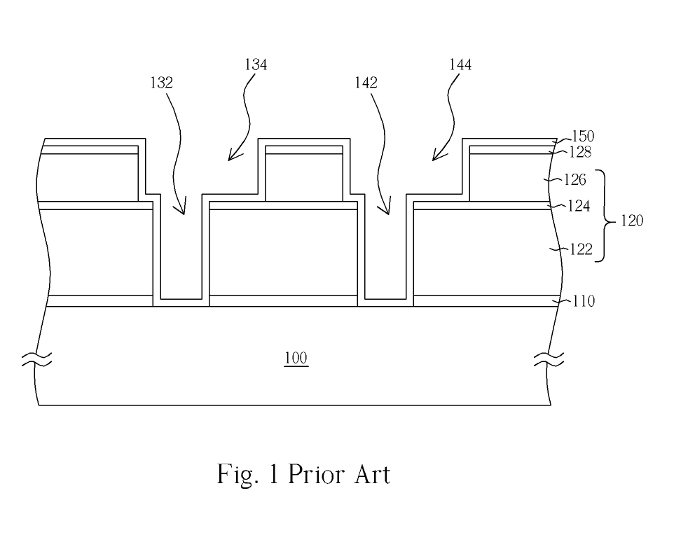

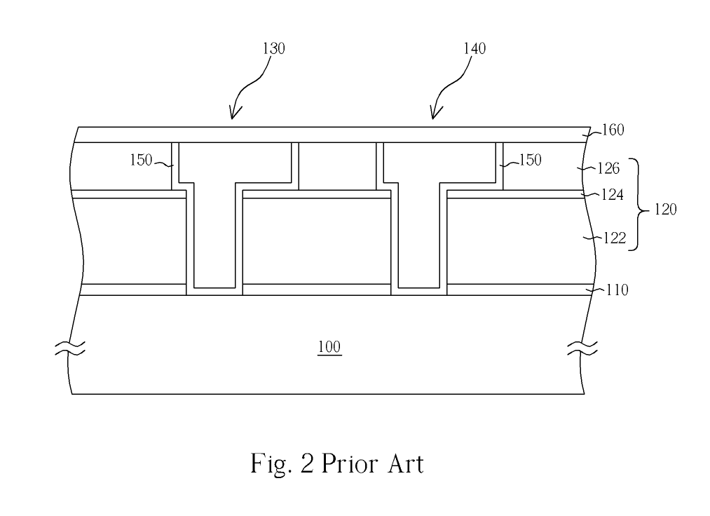

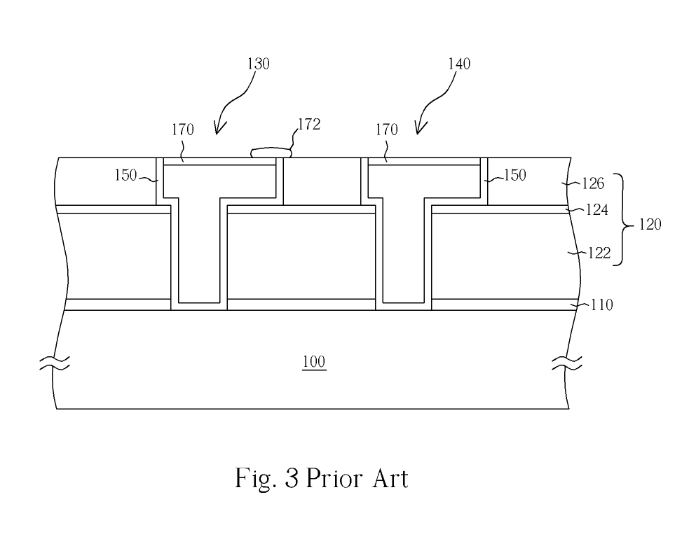

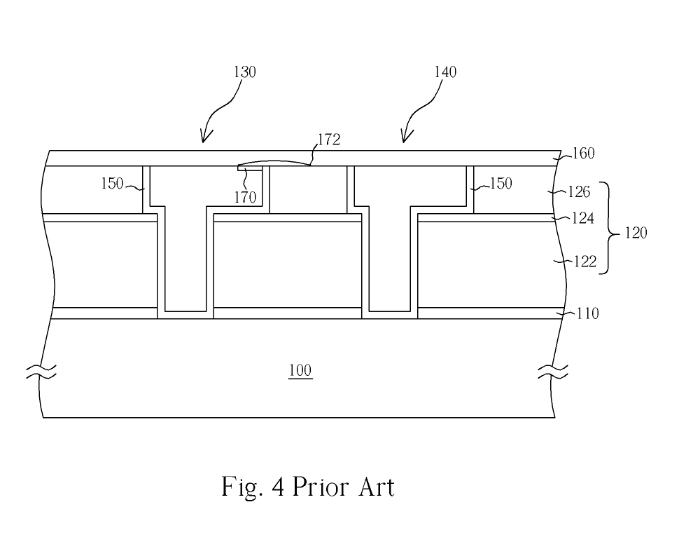

### DETAILED DESCRIPTION

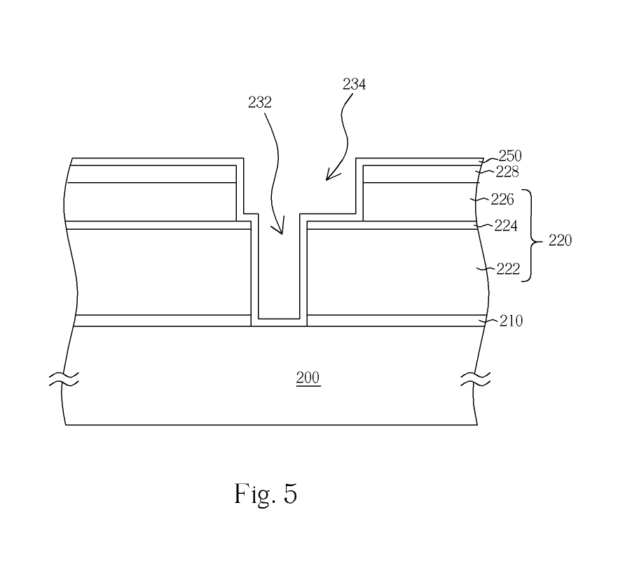

Please refer to FIGS. 5-8, which are schematic drawings illustrating a first preferred embodiment provided by the invention. As shown in FIG. 5, a substrate 200 having a plurality of function devices thereon is provided first (not shown). Then, a cap layer 210, a stacked dielectric layer 220, and a stop layer 228 composed of silicon nitride are sequentially formed on the substrate 200. The stacked dielectric layer 220 comprises a first dielectric layer 222, an etching stop layer 224, and a second dielectric layer 226. The first and second dielectric layers 222 and 226 comprise low dielectric constant (low-k) materials with its dielectric constant lower than 3.5; those dielectric layer also comprises carbon-doped oxide (CDO) or porogen, but are not limited to this. The stacked dielectric layer 220 is formed on the substrate 200 by plasma enhanced chemical vapor disposition (PECVD) method or spin-on coating (SOC) method. Then, at least a via hole 232 and a trench 234 are formed in the cap layer 210, the stacked dielectric layer 220, and the stop layer 228 by a trench-first, via-first, or partial-via-first dual damascene process. Next, a diffusion barrier layer 250 is formed on bottom and sidewalls of the via hole 232 and the trench 234. After forming the diffusion barrier layer 250, a copper metal layer filling the via hole 232 and the trench 234 is formed on the substrate 200 by seed layer and electroplating process.

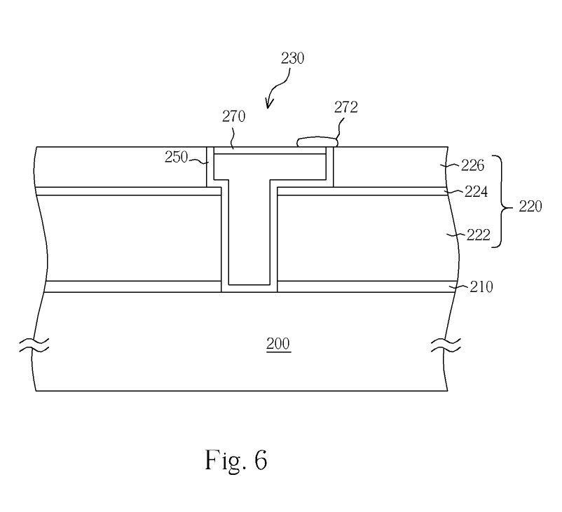

Please refer to FIG. 6. A CMP process is performed to remove surplus copper and the diffusion barrier layer 250 to form a copper damascene structure 230 and another CMP process is performed to remove the stop layer 228 to make the copper damascene structure 230 coplanar with the stacked dielectric layer 220. Additionally, the stop layer 228 can be kept on the stacked dielectric layer 220 instead of being removed. Please refer to FIG. 6 again. Because the organic materials added in the CMP process for protecting the pattern of the copper damascene structure 230 are not easily removed and often remains on the surface of the substrate 200, a heat treatment is performed to remove those impurities 272 left after the CMP process.

The heat treatment provided in the first preferred embodiment can be performed in a furnace, a rapid thermal processing (RTP) chamber, a hot-plate, a PECVD chamber, or a sub-atmospheric chemical vapor deposition (SACVD) chamber. The heat treatment is performed at a temperature in a range of 200-600° C., preferably about 250-450° C.; and it is performed in a duration of 1-600 seconds, preferably about 10-20 seconds. In addition, the heat treatment is performed under an operational pressure in a range of 1.0-760 Torr. The operational pressure is provided by an oxidant gas, a nitrogen, or an insert gas with a flow rate from 100 to about 10,000 standard cubic centimeters per minute (sccm). Furthermore, to completely remove the impurities 272, the heat treatment is performed in cycles, depending on amounts of the impurities 272 and demands for the wafer.

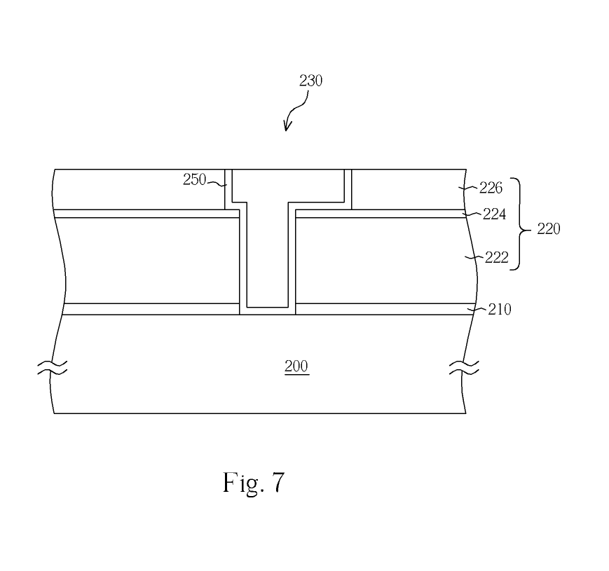

Please refer to FIG. 7. After removing the impurities 272, a reduction plasma treatment with ammonia-containing or hydrogen-containing plasma is performed to reduce the copper oxide 270 formed in the CMP process. Additionally, the heat treatment and the reduction plasma treatment are performed in-situ or ex-situ.

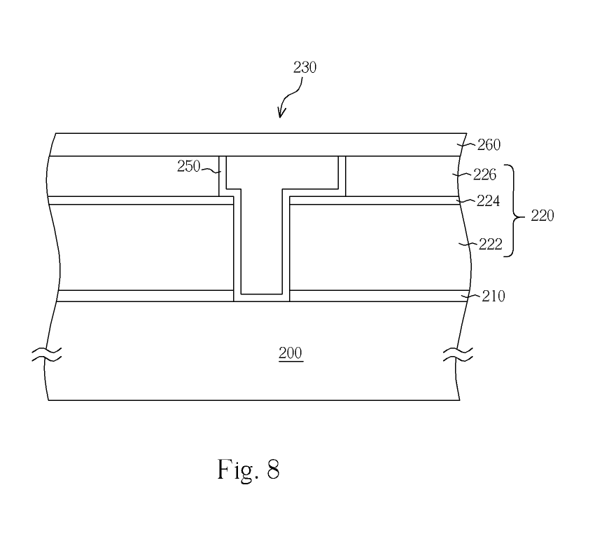

Please refer to FIG. 8. Then a SiN or SiC layer 260 is formed on surfaces of the copper damascene structure 230 and the stacked dielectric layer 220. The SiN or SiC layer 260 not only the protects the copper damascene structure 230 and the stacked dielectric layer 220, but also prevent the copper atom from diffusing along the interface between the copper damascene structure 230 and the surrounding dielectric material.

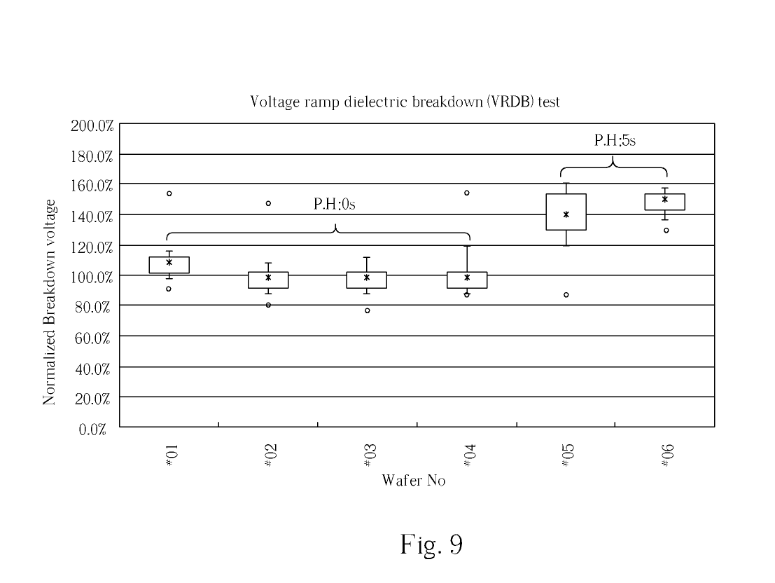

Please refer to FIG. 9, which is a drawing illustrating normalized results of a voltage ramp dielectric breakdown (VRDB) test for conventional damascene structures and that provided by the present invention. As shown in FIG. 9. No. 1-4 wafers have copper damascene structures provided by conventional processes, and the VRDB results of No. 1-4 wafers are normalized as 100%; No. 5-6 wafers have copper damascene structures provided by the copper damascene process according to the present invention. The heat treatment provided in this preferred embodiment is performed about 5 seconds. As shown in FIG. 9, the VRDB results of No. 5-6 wafers indicate that the breakdown voltage of the copper damascene structure provided by the copper damascene process of the present invention is substantially improved about 140%.

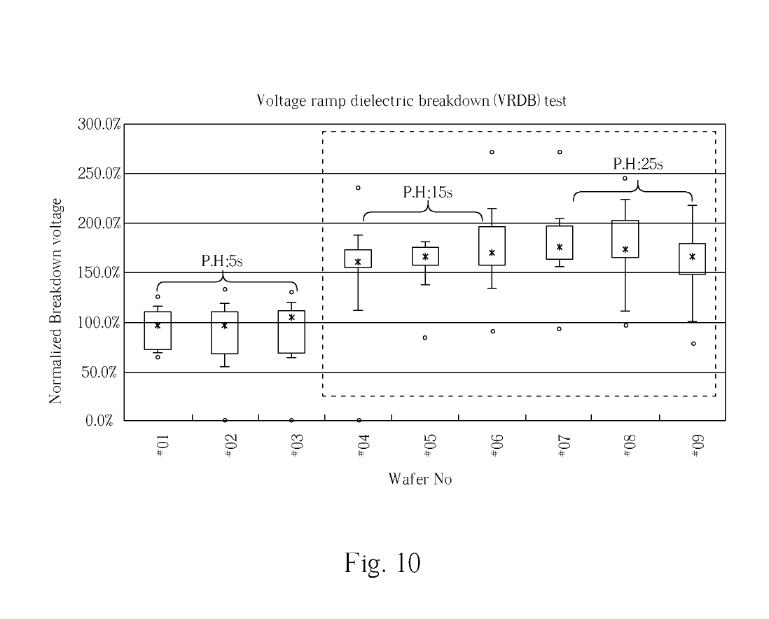

Please refer to FIG. 10, which is a drawing illustrating normalized results of a VRDB test for copper damascene structures provided by the present invention with different procedure parameters. As shown in FIG. 10, No. 1-3 wafers have the copper damascene processes with the heat treatment for 5 seconds, No. 4-6 wafers have the copper damascene processes with the heat treatment for 15 seconds, and No. 7-9 wafers No. 4-6 wafers have the copper damascene processes with the heat treatment for 25 seconds. According to FIG. 10, the VRDB results of No. 1-3 wafers are normalized as 100% while the VRDB results of No. 4-9 wafers achieve 150%, even 200%. To sum up, the VRDB results indicate that copper damascene structures can be effectively improved under heat treatment for at least 15 seconds.

As mentioned above, electrical problems such as reduced breakdown voltage of dielectric layer caused by diffusion of copper atoms, and malfunction of copper damascene structure caused by unreduced copper oxide due to remaining impurities in the conventional copper damascene process are avoided by the present invention and the reliability of the copper damascene structures are effectively improved.

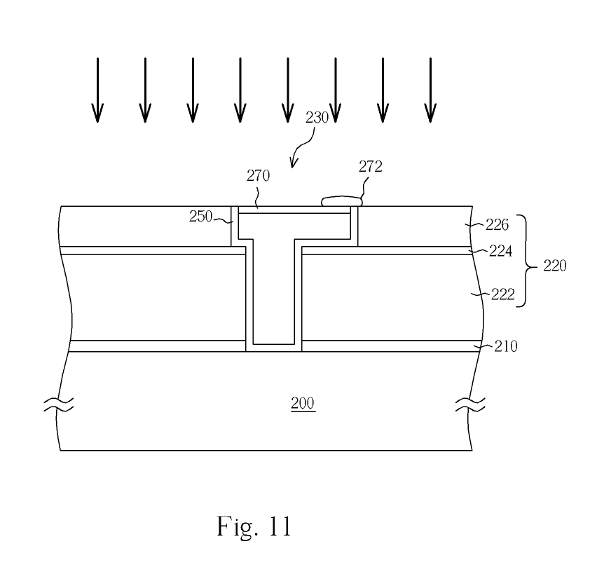

The present invention herein provides a second preferred embodiment. Please refer to FIG. 11, which is a schematic drawing illustrating the second preferred embodiment. Because the steps before CMP process and after the reduction plasma treatment are similar to the steps in the first preferred embodiment, those steps are omitted in the second preferred embodiment. As shown in FIG. 11, to remove the impurities left after the CMP process, the second preferred embodiment herein provides an oxidation plasma treatment after the CMP process. The oxidation plasma treatment comprises an oxidant-containing plasma which can remove the organic materials added for protecting the pattern of the dual damascene structure 230. The oxidation plasma treatment and the reduction plasma treatment can be performed in the same chamber, or in different chambers.

A third preferred embodiment is provided by the present invention herein. Because the steps before CMP and after the reduction plasma treatment are similar to steps in the first preferred embodiment, those steps are omitted in the third preferred embodiment. Please refer to FIG. 11 again. To remove the impurities left after the CMP process, the third preferred embodiment provides a UV treatment after the CMP process. The UV treatment and the reduction plasma treatment are performed in-situ or ex-situ.

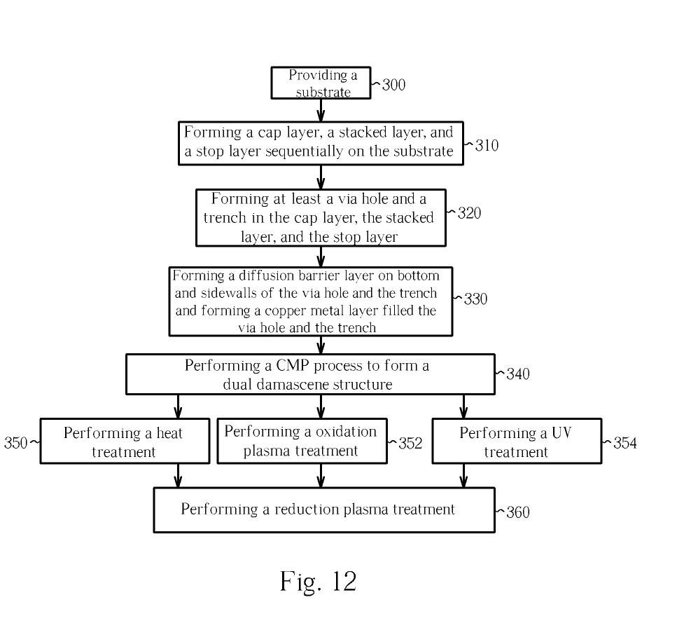

Please refer to FIG. 12, which is a flowchart according to the copper damascene process provided by the invention. The steps are summarized below:

Step 300: providing a substrate having a plurality of function devices within;

Step 310: forming a cap layer, a stacked dielectric layer, and a stop layer sequentially on the substrate. The stacked dielectric layer comprises a first dielectric layer, an etching stop layer, and a second dielectric layer;

Step 320: forming at least a via hole and a trench in the cap layer, the stacked layer, and the stop layer by PEP processes;

Step 330: forming a diffusion barrier layer on bottom and sidewalls of the via hole and the trench and forming a copper layer filling the via hole and the trench;

Step 340: performing a CMP process to remove surplus copper to form a copper damascene structure;

Step 350: performing a heat treatment to remove impurities remaining after CMP process;

Step 352: performing an oxidation plasma treatment to remove impurities remaining after CMP process;

Step 354: performing a UV treatment to remove impurities remaining after CMP process;

Step 360: performing a reduction plasma treatment to reduce copper oxide formed in CMP process.

In the flowchart described above, step 350, step 352, and step 354 are alternative steps.

The object of present invention is achieved by alternatively performing a heat treatment, an oxidation plasma treatment, or a UV treatment which remove residuals generated in the copper damascene process after forming copper damascene structure. Therefore the reduction plasma treatment performed later can reduce copper oxide completely and improve the reliability of the copper damascene structure.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A copper damascene process comprising steps of:
providing a substrate having a dielectric layer formed thereon;
forming at least a copper damascene structure in the dielectric layer;
performing a heat treatment on the substrate; and
performing a reduction plasma treatment on a surface of the copper damascene structure.

2. The copper damascene process of claim 1, wherein the dielectric layer comprises a low dielectric constant (low-k) material with its dielectric constant lower than 3.5.

3. The copper damascene process of claim 1, wherein the dielectric layer comprises carbon-doped oxide (CDO) or porogen.

4. The copper damascene process of claim 1, wherein the dielectric layer is formed on the substrate by plasma enhanced chemical vapor disposition (PECVD) or spin-on coating (SOC).

5. The copper damascene process of claim 1, wherein forming the copper damascene structure further comprises steps:
forming an opening pattern for the copper damascene structure in the dielectric layer;
forming a diffusion barrier layer covering bottom and sidewalls of the opening on the substrate;
forming a copper layer filling the opening; and
performing a chemical mechanical polishing (CMP) process to remove part of the metal layer on the dielectric layer to form the copper damascene structure.

6. The copper damascene process of claim 5, wherein the heat treatment is used to remove impurities left after the CMP process.

7. The copper damascene process of claim 1, wherein the heat treatment is performed at a temperature in a range of 200-600° C.

8. The copper damascene process of claim 7, wherein the heat treatment is performed at a preferred temperature in a range of 250-450° C.

9. The copper damascene process of claim 1, wherein the heat treatment is performed in a duration of 1-600 seconds.

10. The copper damascene process of claim 9, wherein the heat treatment is performed in a preferred duration of 10-60 seconds.

11. The copper damascene process of claim 1, wherein the heat treatment is performed under an operational pressure in a range of 1.0-760 Torr.

12. The copper damascene process of claim 11, wherein the heat treatment further comprises nitrogen or an insert gas used to provide the operational pressure.

13. The copper damascene process of claim 12, wherein the gas has a flow rate in a range of 100-10,000 standard cubic centimeters per minute (sccm).

14. The copper damascene process of claim 11, wherein the heat treatment further comprise an oxidant gas used to provide the operational pressure.

15. The copper damascene process of claim 14, wherein the gas has a flow rate in a range of 100-10,000 standard cubic centimeters per minute (sccm).

16. The copper damascene process of claim 1, wherein the heat treatment is performed in a furnace, a rapid thermal processing (RTP) chamber, a hot-plate, a PECVD chamber, or a sub-atmospheric chemical vapor deposition (SACVD) chamber.

17. The copper damascene process of claim 1, wherein the heat treatment is performed in cycles.

18. The copper damascene process of claim 1, wherein the heat treatment and the reduction plasma treatment are performed in-situ.

19. The copper damascene process of claim 1, wherein the heat treatment and the reduction plasma treatment are performed ex-situ.

20. The copper damascene process of claim 1, wherein the reduction plasma treatment is performed with an ammonia-containing or a hydrogen-containing plasma.

21. The copper damascene process of claim 1 further comprising a step of forming a cap layer on the substrate after the reduction plasma treatment.

22. The copper damascene process of claim 21, wherein the cap layer comprises silicon nitride (SiN) or silicon carbide (SiC).

23. A copper damascene process comprising steps of:
providing a substrate having a dielectric layer formed thereon;
forming at least a copper damascene structure in the dielectric layer;
performing an oxidation plasma treatment on a surface of the substrate; and
performing a reduction plasma treatment on a surface of the copper damascene structure.

24. The copper damascene process of claim 23, wherein the dielectric layer comprises a low dielectric constant (low-k) material with its dielectric constant lower than 3.5.

25. The copper damascene process of claim 23, wherein the dielectric layer comprises carbon-doped oxide (CDO) or porogen.

26. The copper damascene process of claim 23, wherein the dielectric layer is formed on the substrate by PECVD or SOC.

27. The copper damascene process of claim 23, wherein forming the copper damascene structure further comprises steps:
forming an opening pattern for the copper damascene structure in the dielectric layer;
forming a diffusion barrier layer covering bottom and sidewalls of the opening on the substrate;
forming a copper layer filling the opening; and
performing a chemical mechanical polishing (CMP) process to remove part of the metal layer on dielectric layer to form the copper damascene structure.

28. The copper damascene process of claim 27, wherein the oxidation plasma treatment is used to remove impurities left after the CMP process.

29. The copper damascene process of claim 23, wherein the oxidation plasma treatment is performed with an oxidant-containing plasma.

30. The copper damascene process of claim 23, wherein the reduction plasma treatment is performed with an ammonia-containing or a hydrogen-containing plasma.

31. The copper damascene process of claim 23, wherein the oxidation plasma treatment and the reduction plasma treatment are performed in the same chamber.

32. The copper damascene process of claim 23, wherein the oxidation plasma treatment and the reduction plasma treatment are performed in different chambers.

33. The copper damascene process of claim 23 further comprising a step of forming a cap layer on the substrate after the reduction plasma treatment.

34. The copper damascene process of claim 33, wherein the cap layer comprises silicon nitride (SiN) or silicon carbide (SiC).

35. A copper damascene process comprising steps of:
providing a substrate having a dielectric layer formed thereon;
forming at least a copper damascene structure in the dielectric layer;
performing an ultra violet (UV) treatment on a surface of the substrate; and
performing a reduction plasma treatment on a surface of the copper damascene structure.

36. The copper damascene process of claim 35, wherein the dielectric layer comprises a low dielectric constant (low-k) material with its dielectric constant lower than 3.5.

37. The copper damascene process of claim 35, wherein the dielectric layer comprises carbon-doped oxide (CDO) or porogen.

38. The copper damascene process of claim 35, wherein the dielectric layer is formed on the substrate by PECVD or SOC.

39. The copper damascene process of claim 35, wherein forming the copper damascene structure further comprises steps:
forming an opening pattern for the copper damascene structure in the dielectric layer;
forming a diffusion barrier layer covering bottom and sidewalls of the opening on the substrate;
forming a copper layer filling the opening; and
performing a chemical mechanical polishing (CMP) process to remove part of the metal layer on dielectric layer to form the copper damascene structure.

40. The copper damascene process of claim 39, wherein the UV treatment is used to remove impurities left after the CMP process.

41. The copper damascene process of claim 35, wherein the UV treatment and the reduction plasma treatment are performed in-situ.

42. The copper damascene process of claim 35, wherein the UV treatment and the reduction plasma treatment are performed ex-situ.

43. The copper damascene process of claim 35, wherein the reduction plasma treatment is performed with an ammonia-containing or a hydrogen-containing plasma.

44. The copper damascene process of claim 35 further comprising a step of forming a cap layer on the substrate after the reduction plasma treatment.

45. The copper damascene process of claim 44, wherein the cap layer comprises silicon nitride (SiN) or silicon carbide (SiC).
